(19) United States
(12) Patent Application Publication
(10) Pub. No.: US 2025/0151467 A1
(43) Pub. Date: May 8, 2025

(54) LED STRUCTURE AND MANUFACTURING METHOD THEREOF

(71) Applicant: Enkris Semiconductor, Inc., Suzhou (CN)

(72) Inventor: Kai Cheng, Suzhou (CN)

(21) Appl. No.: 18/414,743

(22) Filed: Jan. 17, 2024

(30) Foreign Application Priority Data
Nov. 8, 2023 (CN) 202311481936.6

(51) Int. Cl. H01L 33/20; H01L 25/075; H01L 33/00; H01L 33/16; H01L 33/46; H01L 33/50

(52) U.S. Cl. CPC H10H 20/819; H01L 25/0753; H10H 20/018; H10H 20/817; H10H 20/841; H10H 20/851; H10H 20/0361

(57) ABSTRACT

Provided is an LED structure and a manufacturing method thereof. The LED structure includes a substrate and multiple LED light-emitting units. Multiple grooves are disposed on a side of the substrate, and a first insulating layer is disposed on the substrate between the multiple grooves, where each groove includes at least one epitaxial sidewall, and in the groove, the area of the epitaxial sidewall is greater than the maximum opening area of the groove. Each LED light-emitting unit is located on the at least one epitaxial sidewall of the groove. In this manner, the current density of the LED structure can be reduced, the LED structure can be prevented from generating more heat, and the display effect of the LED structure can be improved.

### CROSS-REFERENCE TO RELATED APPLICATION

This application claims priority to Chinese Patent Application No. CN202311481936.6, filed on Nov. 8, 2023, the disclosure of which is incorporated herein by reference in its entirety.

### TECHNICAL FIELD

The present disclosure relates to the field of semiconductor technologies and, in particular, to a light-emitting diode (LED) structure and a manufacturing method thereof.

### BACKGROUND

In the related art, to achieve high brightness, it is often necessary to inject a relative large current density. However, LED light-emitting units are easily burned out under high current density, and high current density is not conducive to the display effect of the LED structure formed by the LED light-emitting units.

### SUMMARY

The present disclosure provides an LED structure, so as to reduce current density and improve the display effect of the LED structure.

According to an aspect of the present disclosure, an LED structure is provided and includes a substrate and multiple LED light-emitting units.

Multiple grooves are disposed on a side of the substrate, and a first insulating layer is disposed on the substrate between the multiple grooves, where each groove includes at least one epitaxial sidewall, and in a groove, the area of the at least one epitaxial sidewall is greater than the maximum opening area of the groove.

Each LED light-emitting unit is located on the at least one epitaxial sidewall of the groove.

According to another aspect of the present disclosure, a manufacturing method of an LED structure is provided and includes the steps described below.

A substrate is provided and a first insulating layer with multiple patterns is manufactured on the substrate.

The first insulating layer is used as a mask and the substrate is etched to form grooves, where each groove includes at least one epitaxial sidewall, and in the groove, the area of the epitaxial sidewall is greater than the maximum opening area of the groove.

An LED light-emitting unit is epitaxially manufactured on the at least one epitaxial sidewall of the groove.

### BRIEF DESCRIPTION OF DRAWINGS

To illustrate technical solutions in embodiments of the present disclosure more clearly, the drawings used in the description of the embodiments are briefly described below. Apparently, the drawings described below only illustrate part of the embodiments of the present disclosure, and those of ordinary skill in the art may obtain other drawings based on the drawings described below on the premise that no creative work is done.

FIG. 1 is a structural diagram of an LED structure according to embodiment one of the present disclosure;

FIG. 2 is a structural diagram of another LED structure according to embodiment one of the present disclosure;

FIG. 3 is a structural diagram of another LED structure according to embodiment one of the present disclosure;

FIG. 4 is a structural diagram of another LED structure according to embodiment one of the present disclosure;

FIG. 5 is a perspective diagram of a substrate according to embodiment one of the present disclosure;

FIG. 6 is a perspective diagram of another substrate according to embodiment one of the present disclosure;

FIG. 7 is a top diagram of an LED structure according to embodiment one of the present disclosure;

FIG. 8 is a top diagram of another LED structure according to embodiment one of the present disclosure;

FIG. 9 is a sectional diagram of an LED structure taken along a section line AA in FIG. 7;

FIG. 10 is a top diagram of another LED structure according to embodiment one of the present disclosure;

FIG. 11 is a structural diagram of another LED structure according to embodiment one of the present disclosure;

FIG. 12 is a structural diagram of another LED structure according to embodiment one of the present disclosure;

FIG. 13 is a structural diagram of another LED structure according to embodiment one of the present disclosure;

FIG. 14 is a structural diagram of another LED structure according to embodiment one of the present disclosure;

FIG. 15 is a structural diagram of another LED structure according to embodiment one of the present disclosure;

FIG. 16 is a top diagram of another LED structure according to embodiment one of the present disclosure; and

FIG. 17 is a flowchart of a manufacturing method of an LED structure according to embodiment two of the present disclosure.

### DETAILED DESCRIPTION

To make the solutions of the present disclosure better understood by those skilled in the art, the technical solutions in embodiments of the present disclosure are described below clearly and completely in conjunction with drawings in the embodiments of the present disclosure. Apparently, the embodiments described below are part, not all, of the embodiments of the present disclosure. Based on the embodiments of the present disclosure, all other embodiments obtained by those of ordinary skill in the art on the premise that no creative work is done are within the scope of the present disclosure.

It is to be noted that terms “first”, “second”, and the like in the description, claims, and drawings of the present disclosure are used for distinguishing between similar objects and are not necessarily used for describing a particular order or sequence. It is to be understood that the data used in this manner is interchangeable in appropriate cases so that the embodiments of the present disclosure described herein can be implemented in an order not illustrated or described herein. In addition, terms “comprising”, “including”, and any variation thereof are intended to encompass a non-exclusive inclusion. For example, a process, method, system, product, or device that includes a series of steps or units not only includes the expressly listed steps or units, but may also include other steps or units that are not expressly listed or are inherent to such a process, method, product, or device.

### Embodiment One

The embodiment of the present disclosure provides an LED structure. FIG. 1 is a structural diagram of an LED structure according to embodiment one of the present disclosure. FIG. 2 is a structural diagram of another LED structure according to embodiment one of the present disclosure. The LED structure includes a substrate 10 and multiple LED light-emitting units 20. Multiple grooves 11 are disposed on a side of the substrate 10, and a first insulating layer 40 is disposed on the substrate 10 between the multiple grooves 11, where each groove 11 includes at least one epitaxial sidewall A1, and in the groove 11, the area of the epitaxial sidewall A1 is greater than the maximum opening area of the groove 11. Each LED light-emitting unit 20 is located on the at least one epitaxial sidewall A1 of the groove 11.

The substrate 10 may be a composite substrate in which a silicon layer 13 is made on an insulating substrate 12 or a silicon substrate. The material of the first insulating layer 40 may be silicon dioxide, silicon nitride, or other mask materials. The first insulating layer 40 has multiple openings, and the openings of the first insulating layer 40 are used as a mask to make the grooves 11. The shape of the opening of the groove 11 may be consistent with the shape of the bottom surface of the groove 11, and the area of the opening is greater than or equal to the area of the bottom surface of the groove 11. Referring to FIG. 1, in the case where the quadrilateral area of the opening is equal to the quadrilateral area of the bottom surface of the groove 11, in a direction perpendicular to a plane where the substrate 10 is located, the sectional shape of the groove 11 is a rectangle. Referring to FIG. 2, in the case where the quadrilateral area of the opening is greater than the quadrilateral area of the bottom surface of the groove 11, the sectional shape of the groove 11 is an inverted trapezoid. Each LED light-emitting unit 20 is located on the at least one epitaxial sidewall of the groove 11. For example, each epitaxial sidewall of each groove 11 is provided with a respective one LED light-emitting unit 20 thereon; or multiple epitaxial sidewalls of each groove 11 are provided with one LED light-emitting unit 20 thereon; or the multiple epitaxial sidewalls of each groove 11 have different areas, and the LED light-emitting units 20 emitting light of different colors are disposed on the multiple epitaxial sidewalls of each groove 11. Since in a same groove 11, the area of the epitaxial sidewall is greater than the maximum opening area of the groove 11, in the condition of inputting the same current signal, the LED light-emitting unit 20 grown on the epitaxial sidewall has a larger area and a lower current density, thereby preventing the LED structure from generating more heat and improving the display effect of the LED structure.

Optionally, referring to FIGS. 1 and 2, the substrate 10 is a composite substrate in which the silicon layer 13 is made on the insulating substrate 12, the grooves 11 penetrate the silicon layer 13, and the crystal orientation of the Si of the epitaxial sidewall A1 is <111>.

The grooves 11 penetrate the silicon layer 13, and the crystal orientation of the Si of the epitaxial sidewall A1 of the groove is <111> so that the LED light-emitting units 20 can be grown on the epitaxial sidewall A1 of the groove to avoid large-area lattice defects in the LED light-emitting units 20.

Optionally, the insulating substrate 12 is made of the transparent material so that light can be emitted from a side of the insulating substrate 12 facing away from the silicon layer 13.

Optionally, the substrate 10 is a silicon on insulator (SOI) substrate, and the insulating substrate 12 is silicon dioxide and is located between the silicon layer 13 and another silicon layer.

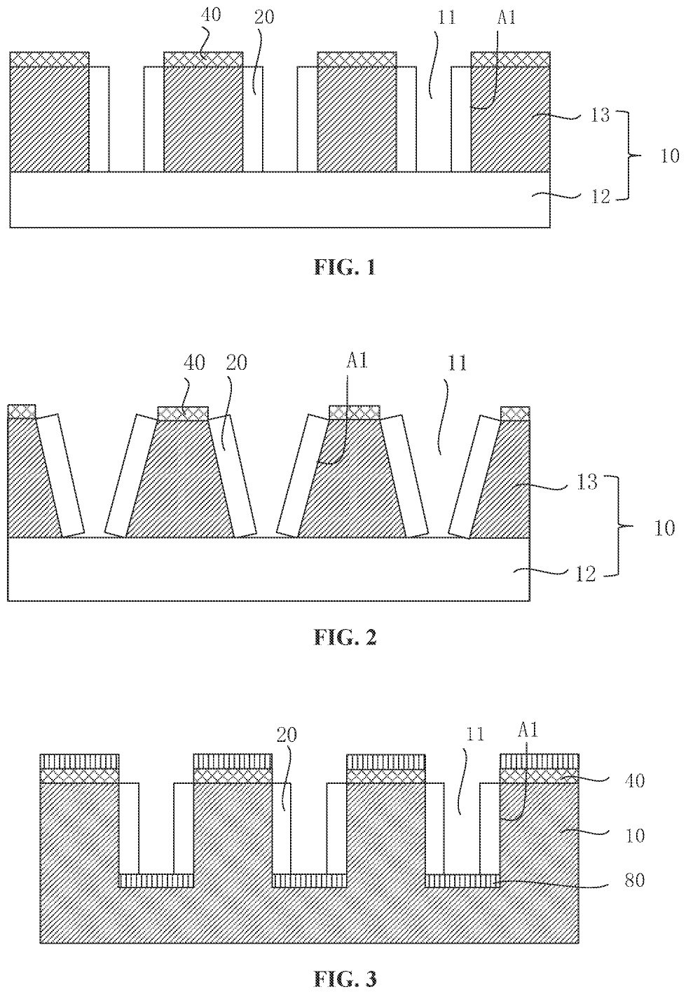

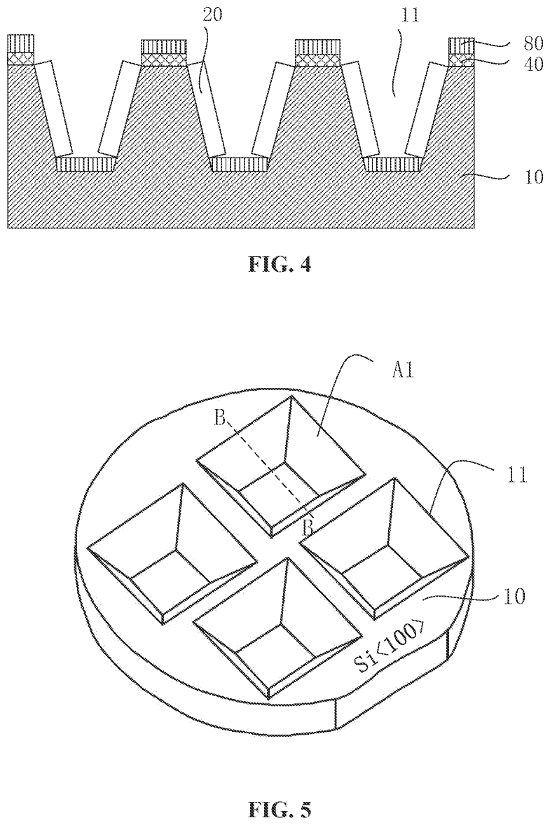

Optionally, FIG. 3 is a structural diagram of another LED structure according to embodiment one of the present disclosure, and FIG. 4 is a structural diagram of another LED structure according to embodiment one of the present disclosure. Referring to FIGS. 3 and 4, the substrate 10 is a silicon substrate, the grooves 11 are located on a side of the silicon substrate, and the crystal orientation of the Si of the epitaxial sidewall A1 is <111>; the LED structure further includes a second insulating layer 80 located at least on bottom surfaces of the grooves 11.

The material of the second insulating layer 80 may be silicon dioxide, silicon nitride, or other insulating materials so that it can be ensured that an electrode can be electrically connected to the LED light-emitting units 20, playing the role of insulation protection.

Optionally, referring to FIGS. 3 and 4, the second insulating layer 80 is also located on a surface of the first insulating layer 40 facing away from the substrate 10.

Optionally, FIG. 5 is a perspective diagram of a substrate according to embodiment one of the present disclosure. Referring to FIGS. 2, 4, and 5, the LED light-emitting unit provided in FIGS. 2 and 4 is manufactured on the epitaxial sidewall A1 of the substrate along a section line BB in FIG. 5, the crystal orientation of the Si of a surface of the substrate 10 facing the first insulating layer 40 is <100>, the angle between the epitaxial sidewall A1 and the bottom surface of the groove 11 is greater than 90°, and the sectional shape of the groove 11 is an inverted trapezoid.

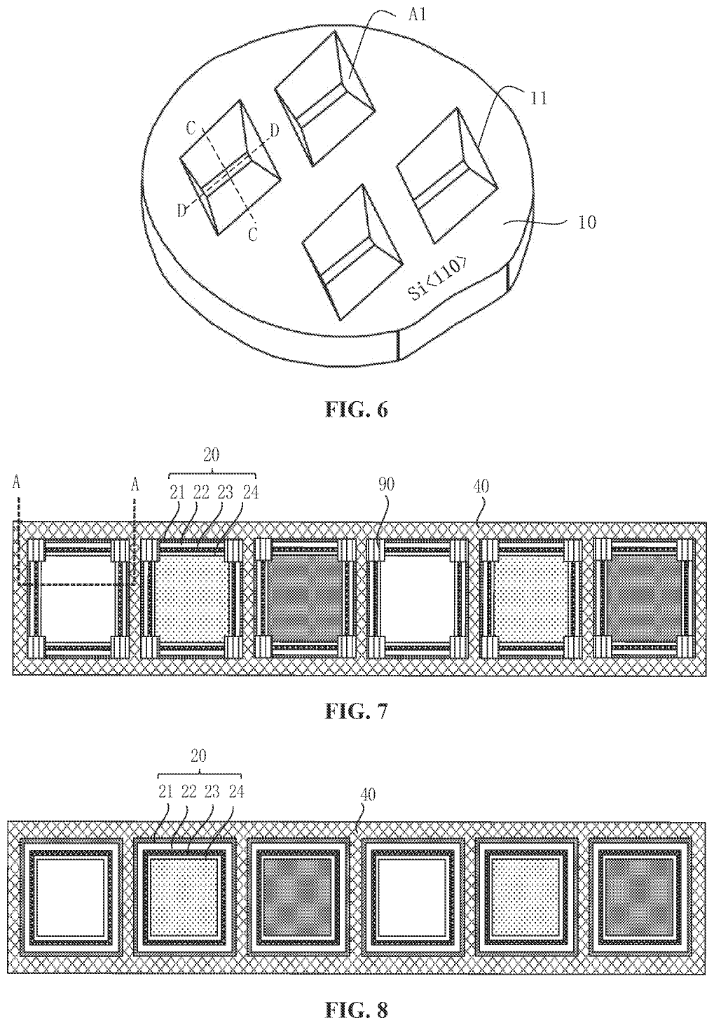

Optionally, FIG. 6 is a perspective diagram of another substrate according to embodiment one of the present disclosure. Referring to FIGS. 1, 3, and 6, the LED light-emitting unit provided in FIGS. 1 and 3 is manufactured on the epitaxial sidewalls of the substrate along a section line CC in FIG. 6, the crystal orientation of the Si of the surface of the substrate 10 facing the first insulating layer 40 is <110>, and the angle between the epitaxial sidewall A1 and the bottom surface of the groove 11 is greater than 90°; or the LED light-emitting unit is manufactured on the epitaxial sidewall A1 of the substrate along a section line DD in FIG. 6, and the angle between the epitaxial sidewall A1 and the bottom surface of the groove 11 is 90°.

It is to be noted that, referring to FIG. 5, in the case where the crystal orientation of the Si of the surface of the substrate 10 facing the first insulating layer 40 is <100>, one groove 11 includes four epitaxial sidewalls A1, and the angle between each epitaxial sidewall A1 and the bottom surface of the groove 11 is greater than 90°.

It is to be noted that in the case where the crystal orientation of the Si of the surface of the substrate 10 facing the first insulating layer 40 is <110>, one groove 11 may include six epitaxial sidewalls, four epitaxial sidewalls are perpendicular to the bottom surface of the groove 11, and two epitaxial sidewalls are opposite and each form an angle greater than 90° with the bottom surface of the groove 11 (not shown in the figure); or referring to FIG. 6, one groove 11 includes four epitaxial sidewalls, two epitaxial sidewalls are opposite and perpendicular to the bottom surface of the groove 11, and two epitaxial sidewalls are opposite and each form an angle greater than 90° with the bottom surface of the groove 11.

In the case where the angle between the epitaxial sidewall and the bottom surface of the groove 11 is greater than 90°, the groove forms a bowl-shaped structure with a larger light emission area, which is conducive to reflecting more light and improving the light emission efficiency.

It is to be noted that, referring to FIGS. 1 to 6, the LED light-emitting unit 20 is grown on the epitaxial sidewall made of silicon. The silicon not only serves as an epitaxial growth point, but also since the silicon is opaque, the sidewall can directly form a bank that blocks optical crosstalk between two grooves 11, thereby avoiding the process of manufacturing the bank later.

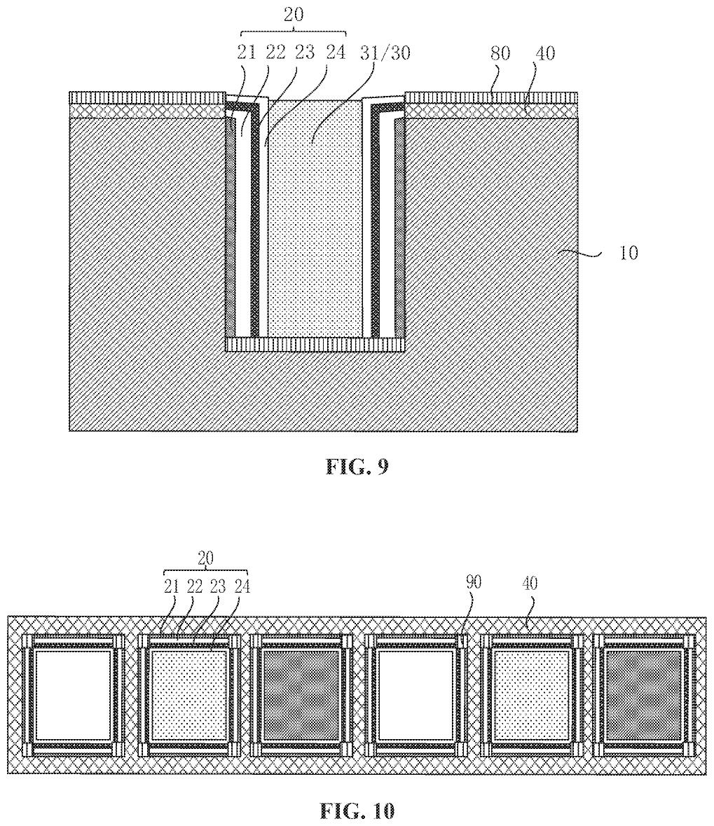

Optionally, FIG. 7 is a top diagram of an LED structure according to embodiment one of the present disclosure, FIG. 8 is a top diagram of another LED structure according to embodiment one of the present disclosure, and FIG. 9 is a sectional diagram of an LED structure taken along a section line AA in FIG. 7. Referring to FIGS. 7 to 9, the LED light-emitting unit 20 includes a buffer layer 21, a first semiconductor layer 22, an active layer 23, and a second semiconductor layer 24 that are stacked in sequence.

The buffer layer 21 is n-type doped, thereby improving the crystal growth quality of the first semiconductor layer 22. For example, the first semiconductor layer 22 may be an n-type semiconductor layer, the second semiconductor layer 24 may be a p-type semiconductor layer, and the active layer 23 may be a light-emitting layer. For example, the active layer 23 may be a blue light-emitting layer, a red light-emitting layer, or a green light-emitting layer.

Optionally, referring to FIG. 9, the first semiconductor layer 22 covers the buffer layer 21, the active layer 23 covers the first semiconductor layer 22, the second semiconductor layer 24 covers the active layer 23, and the second semiconductor layer 24 is not in electrical contact with the substrate 10. Optionally, a nucleation layer (not shown in the figure) is also included between the epitaxial sidewall and the buffer layer 21. Optionally, the preceding layer-by-layer covering structure is formed through lateral epitaxy of semiconductor materials, and an end of each of the first semiconductor layer 22, the active layer 23, or the second semiconductor layer 24 is in contact with the first insulating layer 40 or the second insulating layer 80 so that a short circuit between the first semiconductor layer 22 and the second semiconductor layer 24 due to the contact can be avoided, but also the later production of the electrode electrically connected to the second semiconductor layer 24 is facilitated.

Optionally, the material of the LED structure includes any one of GaN-based materials, GaAs-based materials, or InP-based materials, or a combination thereof.

Optionally, the LED structure further includes a distributed Bragg reflector (DBR) layer located between the LED light-emitting unit and the epitaxial sidewall, where the material of the DBR layer is the semiconductor material. Optionally, along a direction from the epitaxial sidewall to the LED light-emitting unit, the LED light-emitting unit includes the first semiconductor layer, the active layer, and the second semiconductor layer that are stacked in sequence, and the DBR layer is located between the first semiconductor layer and the epitaxial sidewall so that the absorption of light by the substrate material can be prevented and the light emitted by the active layer can be reflected. Optionally, the LED structure further includes the buffer layer and the nucleation layer that are located between the first semiconductor layer and the epitaxial sidewall, and the positional relationship between the DBR layer, the buffer layer, and the nucleation layer is not limited. Optionally, in the case where the material of the LED structure is the GaN-based materials, the DBR layer is formed by a GaN layer and a porous GaN layer.

Optionally, referring to FIG. 7, the LED structure further includes a third insulating layer 90 located at an included angle formed by two adjacent epitaxial sidewalls. The third insulating layer 90 is provided so that multiple independently controllable LED light-emitting units 20 are included in the groove 11. The material of the third insulating layer 90 may be the same as the material of the first insulating layer 40 or the second insulating layer 80, and the details are not repeated here. Optionally, FIG. 7 merely illustrates that one groove includes four epitaxial sidewalls.

Optionally, the opening shape of the groove 11 includes any one of a triangle, a quadrilateral, or a hexagon. It is to be noted that, unless otherwise specified, the case where the opening shape of the groove 11 is a quadrilateral is used as an example in the following embodiments. Optionally, in the case where the opening shape of the groove 11 is a triangle, one groove includes only one epitaxial sidewall, and one LED light-emitting unit is provided correspondingly; in the case where the opening shape of the groove 11 is a quadrilateral, one groove may include four epitaxial sidewalls, and four LED light-emitting units are provided correspondingly; and in the case where the opening shape of the groove 11 is a hexagon, one groove may include six epitaxial sidewalls, and six LED light-emitting units are provided correspondingly.

Optionally, referring to FIG. 8, the buffer layer 21, the first semiconductor layer 22, the active layer 23, and the second semiconductor layer 24 form a structure surrounding inner sides of the groove 11. An electrical signal is transmitted to the first semiconductor layer 22 of the annular structure, an electrical signal is transmitted to the second semiconductor layer 24 of the annular structure, and the active layers 23 on different sidewalls are controlled at the same time.

Optionally, FIG. 10 is a top diagram of another LED structure according to embodiment one of the present disclosure. Referring to FIG. 10, the third insulating layer 90 isolates only the buffer layers 21, the first semiconductor layers 22, and the active layers 23 on adjacent epitaxial sidewalls located in the groove 11, and the second semiconductor layers 24 on four epitaxial sidewalls form the structure surrounding the inner sides of the groove 11. The second semiconductor layers 24 of the annular structure share one electrical signal and another electrical signal is transmitted to four first semiconductor layers 22 in the groove 11. Therefore, the active layers 23 in the groove 11 are independently controllable.

It is to be noted that the electrical signal may be a current magnitude signal, a voltage magnitude signal, or a switching signal.

It is to be noted that the area of the epitaxial sidewalls is the area of the four sidewalls of the groove 11 minus the area covered by the third insulating layer 90, that is, the effective sidewall area for growing the LED light-emitting unit 20. The effective sidewall area is greater than the maximum opening area of the groove 11 so that in the condition of inputting the same current signal, the current density can be reduced, thereby preventing the LED structure from generating more heat and improving the display effect of the LED structure.

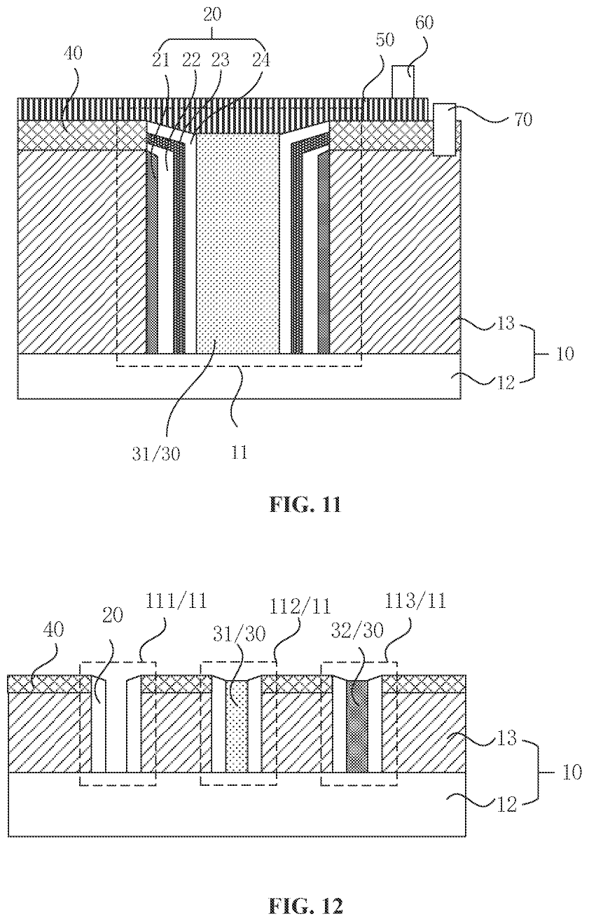

Optionally, FIG. 11 is a structural diagram of another LED structure according to embodiment one of the present disclosure. Referring to FIG. 11, the LED structure further includes a first electrode 60 electrically connected to the second semiconductor layer 24.

Optionally, referring to FIG. 11, the LED structure further includes a current expansion layer 50 located on a side of the first insulating layer 40 facing away from the substrate 10, where the current expansion layer 50 is in contact with the second semiconductor layer 24, and the first electrode 60 is electrically connected to the second semiconductor layer 24 through the current expansion layer 50.

In the case where the substrate 10 is a silicon substrate, the current expansion layer 50 is an indium tin oxide (ITO) layer, and the ITO layer has good conductivity and visible light transmittance so that the light emitted by the LED light-emitting unit can be emitted through the current expansion layer 50. In the case where the substrate 10 is a composite substrate in which the silicon layer 13 is grown on the insulating substrate 12, the current expansion layer 50 may be a metal alloy layer, the light emitted by the LED light-emitting unit can be emitted from the insulating substrate, and in this case, the insulating substrate is a transparent substrate. Referring to FIG. 11, one current expansion layer 50 may cover one groove, and the current expansion layer 50 may be in contact with and electrically connected to all the second semiconductor layers 24 in one groove. In this case, all the LED light-emitting units in the groove 11 are controlled simultaneously. Optionally, in the LED structure shown in FIG. 7, one current expansion layer 50 (not shown in FIG. 7) may cover only one epitaxial sidewall, that is, four second semiconductor layers 24 in the groove 11 are controlled by four current expansion layers 50, that is, four LED light-emitting units 20 in the groove 11 are independently controllable.

It is to be noted that FIG. 9 illustrates that the substrate 10 is a silicon substrate, so the second insulating layer 80 is disposed on the bottom surface of the groove to facilitate the subsequent production of the electrode; FIG. 11 illustrates that the substrate 10 is a composite substrate, so the second insulating layer is not disposed on the bottom surface of the groove, and the insulating properties of the insulating substrate 12 are used to facilitate the subsequent production of the electrode.

If the conductivity type of the second semiconductor layer 24 is P-type, the first electrode 60 is an anode. The first electrode 60 is electrically connected to the second semiconductor layer 24 through the current expansion layer 50 to provide an electrical signal for the second semiconductor layer 24.

Optionally, the LED structure further includes a second electrode 70. The second electrode 70 penetrates the first insulating layer 40 and is in contact with the substrate 10, the substrate 10 and the buffer layer 21 include N-type doped materials, and the second electrode 70 is electrically connected to the first semiconductor layer 22 through the substrate 10 and the buffer layer 21.

The substrate 10 and the buffer layer 21 include a N-type doped material so that the substrate 10 and the buffer layer 21 are conductive. The second electrode 70 is a cathode and may be electrically connected to the first semiconductor layer 22 through the substrate 10 and the buffer layer 21 to provide an electrical signal for the first semiconductor layer 22. In this case, the LED structure controls the electrical signal through the common cathode.

Optionally, referring to FIGS. 1 and 2, the maximum width of a shape of a vertical projection of the groove 11 on the substrate 10 is 2 to 50 μm, and the depth of the groove 11 is greater than 0.25 times the maximum width of the groove 11.

In the case where the maximum width of the shape of the vertical projection of the groove 11 on the substrate 10 is less than 2 μm, the process is complicated; in the case where the maximum width of the shape of the vertical projection of the groove 11 on the substrate 10 is greater than 50 μm, the dimension of the device structure is too large, which is not conducive to integration; therefore, in the case where the maximum width of the shape of the vertical projection of the groove 11 on the substrate 10 is configured to be 2 to 50 μm, the process is simple, and the operation is easy, which is conducive to integration. The depth of the groove 11 is greater than the maximum width so that the LED light-emitting unit grown on the epitaxial sidewall in the condition of inputting the same current signal has a larger area and a lower current density, thereby preventing the LED structure from generating more heat and improving the display effect of the LED structure. Optionally, the width of the shape of the vertical projection of the groove 11 on the substrate 10 is 2 μm, 5 μm, 10 μm, 20 μm, or 50 μm.

The depth of the groove 11 is greater than 0.25 times the maximum width of the groove 11 so that the area of the epitaxial sidewall in the groove is greater than the maximum opening area of the groove. Optionally, the maximum depth of the groove 11 may be controlled according to silicon substrates with different crystal orientations. For example, the groove shown in FIG. 5 is made on Si<100>, and the maximum depth of the groove is 0.7 times the width of the groove.

Optionally, referring to FIG. 7, the LED light-emitting units 20 emitting light of the same color are disposed on the multiple epitaxial sidewalls in each groove 11.

Referring to FIG. 7, one LED light-emitting unit 20 is separately disposed on each epitaxial sidewall of each groove 11, the multiple LED light-emitting units 20 formed on the multiple epitaxial sidewalls of one groove 11 emit light of the same color, and the multiple LED light-emitting units 20 formed in multiple grooves emit light of the same color; or referring to FIG. 8, one LED light-emitting unit 20 is disposed on multiple epitaxial sidewalls of each groove 11, one LED light-emitting unit 20 is formed in one groove, and the multiple LED light-emitting units 20 formed in multiple grooves emit light of the same color. For example, the LED light-emitting unit 20 may be a blue LED light-emitting unit. For example, the LED light-emitting unit 20 may also be a red LED light-emitting unit or a green LED light-emitting unit.

Optionally, FIG. 12 is a structural diagram of another LED structure according to embodiment one of the present disclosure. Referring to FIGS. 11 and 12, the LED structure further includes a first light conversion layer 301 located between the multiple LED light-emitting units 20 in the groove 11 and configured to perform color conversion on light emitted by the LED light-emitting units 20. Optionally, the first light conversion layer 301 covers part of the side surface of the LED light-emitting unit 20 facing away from the epitaxial sidewall.

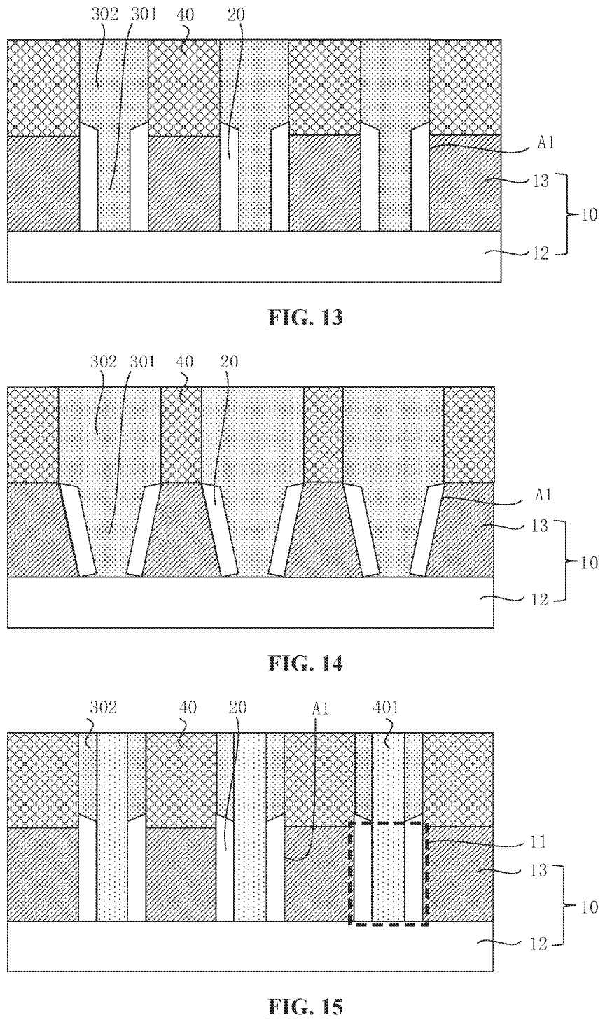

Optionally, FIG. 13 is a structural diagram of another LED structure according to embodiment one of the present disclosure. Referring to FIG. 13, the LED structure further includes a second light conversion layer 302 located on a side of the LED light-emitting unit 20 facing away from the substrate 10.

Optionally, referring to FIG. 13, the second light conversion layer 302 is located on a side of the first light conversion layer 301 facing away from the substrate 10. Optionally, referring to FIG. 13, along a direction from the silicon layer 13 to the first insulating layer 40, the thickness of both the first light conversion layer 301 and the second light conversion layer 302 is not less than 10 μm, so as to improve the light conversion efficiency of the light conversion layers.

Optionally, referring to FIG. 13, the epitaxial sidewall A1 is perpendicular to the insulating substrate 12. Optionally, FIG. 14 is a structural diagram of another LED structure according to embodiment one of the present disclosure. Referring to FIG. 14, the epitaxial sidewall A1 is not perpendicular to the insulating substrate 12.

Optionally, FIG. 15 is a structural diagram of another LED structure according to embodiment one of the present disclosure. Referring to FIG. 15, after the LED light-emitting unit 20 is epitaxially manufactured on the epitaxial sidewall A1 of the groove 11, the second light conversion layer 302 is disposed on a side of the LED light-emitting unit 20 facing away from the insulating substrate 12, and the thickness of the second light conversion layer 302 is not less than 10 μm, thereby improving the light conversion efficiency of the light conversion layer; a light-blocking layer 401 is disposed between the multiple LED light-emitting units 20 in the groove 11 so that the multiple LED light-emitting units 20 that independently emit light are included in one groove 11, thereby improving the resolution.

The materials of the first light conversion layer 301 and the second light conversion layer 302 include any one of phosphors or quantum dots so that the light of the LED light-emitting unit can be converted into light of any color through the first light conversion layer 301 and the second light conversion layer 302, thereby achieving the full-color display.

Optionally, referring to FIG. 11, the upper surface of the first light conversion layer 301 is lower than the upper surface of the second semiconductor layer 24, the upper surface of the second semiconductor layer 24 is the surface facing away from the insulating substrate 12, and the first light conversion layer 301 does not cover the upper surface of the second semiconductor layer 24 so that the current expansion layer 50 is electrically connected to the second semiconductor layer 24.

Optionally, referring to FIG. 12, the groove 11 includes a first groove 111, a second groove 112, and a third groove 113; the first light conversion layer 301 includes a first color light conversion layer 31 and a second color light conversion layer 32, the first color light conversion layer 31 is configured to convert the light of a first color emitted by the LED light-emitting unit 20 into a second color, and the second color light conversion layer 32 is configured to convert the light of the first color emitted by the LED light-emitting unit 20 into a third color; the second groove 112 is filled with the first color light conversion layer 31, and the third groove 113 is filled with the second color light conversion layer 32.

The LED light-emitting unit 20 may be the blue LED light-emitting unit, the first color light conversion layer 31 may convert the blue light emitted by the blue LED light-emitting unit into green light, and the second color light conversion layer 32 may convert the blue light emitted by the blue LED light-emitting unit into red light, thereby achieving the full-color display of the LED structure. Optionally, the LED light-emitting unit 20 may be the blue LED light-emitting unit, and the first groove 111 is filled with brightening materials, blue phosphors, or blue quantum dots, thereby improving the purity and luminescence efficiency of the blue light in the first groove 111.

Optionally, FIG. 16 is a top diagram of another LED structure according to embodiment one of the present disclosure. Referring to FIG. 16, the multiple epitaxial sidewalls of each groove 11 have different areas, and the LED light-emitting units 20 emitting light of different colors are disposed on the multiple epitaxial sidewalls of each groove 11.

The multiple epitaxial sidewalls of each groove 11 have different areas. The smaller the area, the faster the In incorporation rate/the slower the A1 incorporation rate, the longer the wavelength of the light emitted by the active layer in the LED light-emitting unit 20 so that three LED light-emitting units 20 with different colors of light can be grown in one groove 11. Optionally, the multiple LED light-emitting units 20 in one groove 11 are independently controlled to emit light simultaneously, the light is mixed into white light and emitted, and finally, the LED structure as a whole emits the white light. Optionally, the multiple LED light-emitting units 20 in one groove 11 are independently controlled to not emit light simultaneously, and finally, the LED structure is used for the full-color display.

Optionally, referring to FIG. 16, the LED light-emitting units 20 include a first color LED light-emitting unit 201, a second color LED light-emitting unit 202, and a third color LED light-emitting unit 203; and the first color LED light-emitting unit 201, the second color LED light-emitting unit 202, and the third color LED light-emitting unit 203 are separately disposed on the epitaxial sidewalls having different areas in each groove 11.

The first color LED light-emitting unit 201 is the blue LED light-emitting unit, the second color LED light-emitting unit 202 is the green LED light-emitting unit, and the third color LED light-emitting unit 203 is the red LED light-emitting unit.

Optionally, in each groove 11, the third insulating layer 90 is disposed between two adjacent epitaxial sidewalls so that the multiple epitaxial sidewalls of each groove 11 have different areas. Optionally, the LED light-emitting units are grown only on the epitaxial sidewalls. The LED light-emitting units are grown on the epitaxial sidewalls with different areas so that the LED light-emitting units emitting light of three colors are in one groove.

It is to be noted that FIG. 16 only uses the inverted trapezoidal groove with four epitaxial sidewalls formed in the Si<100> crystal orientation as an example. In the groove with six epitaxial sidewalls formed in the Si<110> crystal orientation, two groups of epitaxial sidewalls are formed through the third insulating layer, and each group of epitaxial sidewalls includes three epitaxial sidewalls with different areas. After the LED light-emitting units are grown, two groups of the LED light-emitting units emitting light of three colors are included in one groove.

### Embodiment Two

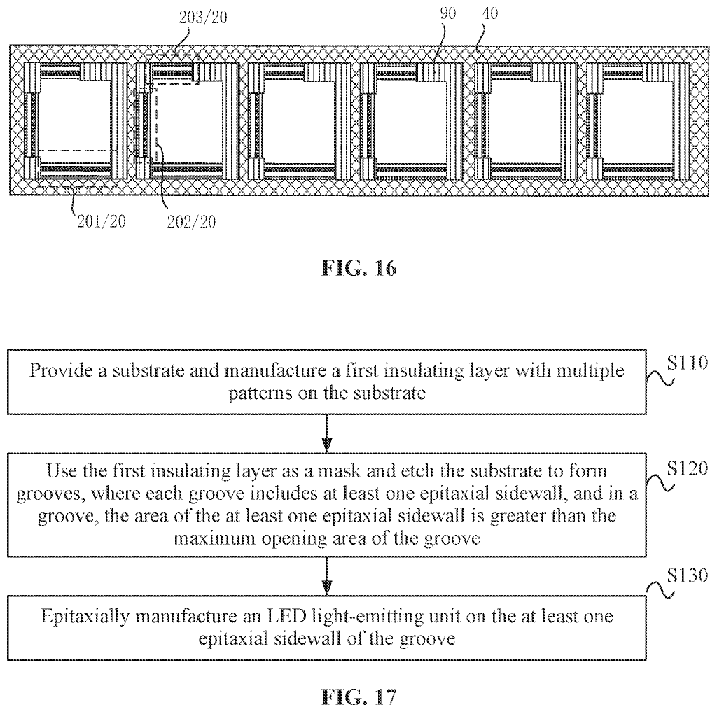

Based on the preceding embodiment, the embodiment of the present disclosure provides a manufacturing method of an LED structure. FIG. 17 is a flowchart of a manufacturing method of an LED structure according to embodiment two of the present disclosure. Referring to FIG. 17, the manufacturing method includes the steps described below.

In S110, a substrate is provided and a first insulating layer with multiple patterns is manufactured on the substrate.

In S120, the first insulating layer is used as a mask and the substrate is etched to form grooves, where each groove includes at least one epitaxial sidewall, and in a groove, the area of the at least one epitaxial sidewall is greater than the maximum opening area of the groove.

In S130, an LED light-emitting unit is epitaxially manufactured on the at least one epitaxial sidewall of the groove.

Referring to FIGS. 1 and 2, the first insulating layer 40 with multiple openings may be manufactured on the substrate 10 through processes such as photolithography or wet etching.

Optionally, the crystal orientation of the Si of the sidewall on which the LED light-emitting unit is epitaxially manufactured is <111>, and the grooves shown in FIG. 5 may be formed by etching silicon materials with a crystal orientation of <100>, or the grooves shown in FIG. 6 may be formed by etching silicon materials with a crystal orientation of <110>. Optionally, the sidewall is treated by using an alkaline solution so as to form the Si<111> crystal orientation.

Optionally, the LED light-emitting units emitting light of the same color are disposed on the multiple epitaxial sidewalls of each groove. After the LED light-emitting unit is epitaxially manufactured on at least one epitaxial sidewall of the groove, the manufacturing method further includes filling a light conversion layer between the multiple LED light-emitting units in the groove, where the light conversion layer covers part of the LED light-emitting units and is configured to perform color conversion on light emitted by the LED light-emitting units.

The light conversion layer can perform color conversion on the light emitted by the LED light-emitting units to achieve the full-color display.

The LED structure provided in the technical solutions of the embodiments of the present disclosure includes a substrate and multiple LED light-emitting units. Multiple grooves are disposed on a side of the substrate, and a first insulating layer is disposed on the substrate between the multiple grooves, where each groove includes at least one epitaxial sidewall, and in the groove, the area of the epitaxial sidewall is greater than the maximum opening area of the groove. Each LED light-emitting unit is located on the at least one epitaxial sidewall of the groove. Since in the groove, the area of the at least one epitaxial sidewall is greater than the maximum opening area of the groove, the LED light-emitting unit grown on the epitaxial sidewall under the same current density has a larger area and a lower current density, thereby reducing the current density of the LED structure and improving the display effect of the LED structure.

It is to be understood that various forms of processes shown above may be adopted with steps reordered, added, or deleted. For example, the steps described in the present disclosure may be performed in parallel, sequentially, or in different sequences, as long as the desired results of the technical solutions of the present disclosure can be achieved, and no limitation is imposed herein.

What is claimed is:

1. A light-emitting diode (LED) structure, comprising:
a substrate, wherein a plurality of grooves are disposed on a side of the substrate, and a first insulating layer is disposed on the substrate between the plurality of grooves, wherein each groove of the plurality of grooves comprises at least one epitaxial sidewall, and in a groove of the plurality of grooves, an area of the at least one epitaxial sidewall is greater than a maximum opening area of the groove; and
a plurality of LED light-emitting units, wherein each LED light-emitting unit of the plurality of LED light-emitting units is located on the at least one epitaxial sidewall of the groove.

2. The LED structure of claim 1, wherein the substrate is a composite substrate in which a silicon layer is made on an insulating substrate, the plurality of grooves penetrate the silicon layer, and a crystal orientation of Si of the at least one epitaxial sidewall is <111>.

3. The LED structure of claim 1, wherein the substrate is a silicon substrate, the plurality of grooves are located on a side of the silicon substrate, and a crystal orientation of Si of the at least one epitaxial sidewall is <111>;
wherein the LED structure further comprises a second insulating layer located at least on bottom surfaces of the plurality of grooves.

4. The LED structure of claim 2, wherein in a case where a crystal orientation of Si of a surface of the substrate facing the first insulating layer is <100>, an angle between the epitaxial sidewall and a bottom surface of the groove is greater than 90°; or
in a case where the crystal orientation of the Si of the surface of the substrate facing the first insulating layer is <110>, the angle between the epitaxial sidewall and the bottom surface of the groove is greater than or equal to 90°.

5. The LED structure of claim 1, wherein an LED light-emitting unit of the plurality of LED light-emitting units comprises a buffer layer, a first semiconductor layer, an active layer, and a second semiconductor layer that are stacked in sequence.

6. The LED structure of claim 5, wherein the each groove comprises a plurality of epitaxial sidewalls, and the structure further comprises a third insulating layer located at an included angle formed by two adjacent epitaxial sidewalls of the plurality of epitaxial sidewalls, wherein the third insulating layer is provided so that the plurality of LED light-emitting units are independently comprised in the groove.

7. The LED structure of claim 5, wherein the buffer layer, the first semiconductor layer, the active layer, and the second semiconductor layer form a structure surrounding inner sides of the groove so that one independent LED light-emitting unit is comprised in the groove.

8. The LED structure of claim 5, wherein the first semiconductor layer covers the buffer layer, the active layer covers the first semiconductor layer, and the second semiconductor layer covers the active layer.

9. The LED structure of claim 8, further comprising:
a first electrode electrically connected to the second semiconductor layer.

10. The LED structure of claim 9, further comprising:
a current expansion layer located on a side of the first insulating layer facing away from the substrate, wherein the current expansion layer is in contact with the second semiconductor layer; and
the first electrode is electrically connected to the second semiconductor layer through the current expansion layer.

11. The LED structure of claim 10, further comprising:
a second electrode, wherein the second electrode penetrates the first insulating layer and is in contact with the substrate, the substrate and the buffer layer comprise an N-type doped material, and the second electrode is electrically connected to the first semiconductor layer through the substrate and the buffer layer.

12. The LED structure of claim 1, wherein a maximum width of a shape of a vertical projection of the groove on the substrate is 2 to 50 μm, and a depth of the groove is greater than 0.25 times the maximum width of the groove.

13. The LED structure of claim 1, wherein the each groove comprises a plurality of epitaxial sidewalls, and a plurality of LED light-emitting units emitting light of a same color are disposed on the plurality of epitaxial sidewalls of the each groove.

14. The LED structure of claim 13, further comprising:
a first light conversion layer located between the plurality of LED light-emitting units in the groove.

15. The LED structure of claim 13, further comprising:
a second light conversion layer located on a side of the LED light-emitting unit facing away from the substrate.

16. The LED structure of claim 1, further comprising:
a distributed Bragg reflector (DBR) layer located between an LED light-emitting unit of the plurality of LED light-emitting units and the epitaxial sidewall, wherein material of the DBR layer is a semiconductor material.

17. The LED structure of claim 1, wherein a plurality of epitaxial sidewalls of the each groove have different areas, and the plurality of LED light-emitting units emitting light of different colors are disposed on the plurality of epitaxial sidewalls of the groove.

18. The LED structure of claim 16, wherein the each groove comprises a plurality of epitaxial sidewalls and in the each groove, a third insulating layer is disposed between two adjacent epitaxial sidewalls of the plurality of epitaxial sidewalls so that the plurality of epitaxial sidewalls of the each groove have different areas.

19. A manufacturing method of a light-emitting diode (LED) structure, comprising:
providing a substrate and manufacturing a first insulating layer with a plurality of patterns on the substrate;
using the first insulating layer as a mask and etching the substrate to form grooves, wherein each groove of the plurality of grooves comprises at least one epitaxial sidewall, and in a groove of the plurality of grooves, an area of an epitaxial sidewall of the at least one epitaxial sidewall is greater than a maximum opening area of the groove; and
epitaxially manufacturing an LED light-emitting unit on the at least one epitaxial sidewall of the groove.

20. The manufacturing method of claim 19, wherein a plurality of LED light-emitting units emitting light of a same color are disposed on a plurality of epitaxial sidewalls of the each groove;
wherein a plurality of LED light-emitting units are provided, and after the LED light-emitting unit is epitaxially manufactured on the at least one epitaxial sidewall of the groove, the manufacturing method further comprises:
filling a light conversion layer between the plurality of LED light-emitting units in the groove, wherein the light conversion layer covers part of the plurality of LED light-emitting units and is configured to perform color conversion on light emitted by the plurality of LED light-emitting units.
